(19) United States
(12) Patent Application Publication
(10) Pub. No.: US 2015/0049843 A1
(43) Pub. Date: Feb. 19, 2015

(54) Combined Transmission Precompensation and Receiver Nonlinearity Mitigation

(71) Applicant: MagnaCom Ltd., Moshav Ben Shemen (IL)

(72) Inventors: Ilan Reuven, Ganey Tikva (IL); Amir Eliaz, Moshav Ben Shemen (IL)

(21) Appl. No.: 14/461,090

(22) Filed: Aug. 15, 2014

Related U.S. Application Data
(60) Provisional application No. 61/866,076, filed on Aug. 15, 2013.

(51) Int. Cl. H04B 1/04; H03F 1/32

(52) U.S. Cl. CPC H04B 1/0475; H03F 1/3247; H03F 1/3258; H03F 2201/3233; H03F 2201/3227; H04B 2001/0408
USPC 375/297; 375/296

(57) ABSTRACT

Circuitry of a transmitter may comprise a predistortion circuit cascaded with a nonlinear circuit. The nonlinear circuit may be characterized by a first response corresponding to a first error vector magnitude. A response of the predistortion circuit may be configured based on the first response of the nonlinear circuit such that a composite response of the predistortion circuit cascaded with the nonlinear circuit differs from the first response and is characterized by a second error vector magnitude that is greater or equal than the first error vector magnitude. The response of the predistortion circuit may be configured based on feedback of an output of the nonlinear circuit. The response of the predistortion circuit may be configured based on parameters received from a receiver partner of the transmitter during connection setup, in preambles, in message headers, and/or in dedicated messages.

### PRIORITY CLAIM

This application claims the benefit of priority to U.S. provisional patent application 61/866,076 titled “Combined Transmission Precompensation and Receiver Nonlinearity Mitigation” and filed on Aug. 15, 2013, which is hereby incorporated herein by reference.

### TECHNICAL FIELD

Certain embodiments of the invention relate to electronic communications. More specifically, certain embodiments of the invention relate to methods and systems for combined transmission precompensation and receiver nonlinearity mitigation.

### BACKGROUND

Limitations and disadvantages of conventional and traditional approaches to electronic communication will become apparent to one of skill in the art, through comparison of such systems with some aspects of the present invention as set forth in the remainder of the present application with reference to the drawings.

### BRIEF SUMMARY OF THE DISCLOSURE

Aspects of the present disclosure are directed to a method and system for improving the efficiency and performance of digital communications systems that are subject to nonlinear distortion.

Various advantages, aspects and novel features of the present disclosure, as well as details of an illustrated embodiment thereof, will be more fully understood from the following description and drawings.

### BRIEF DESCRIPTION OF DRAWINGS

FIG. 1 is a qualitative curve that illustrates a typical output power versus input power characteristic of a power amplifier

FIG. 2 is a block diagram illustrating a system that employs digital preprocessing circuitry preceding nonlinear circuitry

FIG. 3 is a qualitative curve that illustrates the composite response of a transmitter with and without conventional predistortion.

FIG. 4 is a block diagram of a receiver configured for receiver-aided mitigation of nonlinear effects

FIGS. 5A and 5B depict an example sequence-estimation-based implementation of the receiver of receiver FIG. 4.

FIG. 6 is a flowchart illustrating an example process for configuration of a transmitter.

FIG. 7 is a flowchart illustrating an example process for configuration of a transmitter.

### DETAILED DESCRIPTION

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled, or not enabled, by some user-configurable setting.

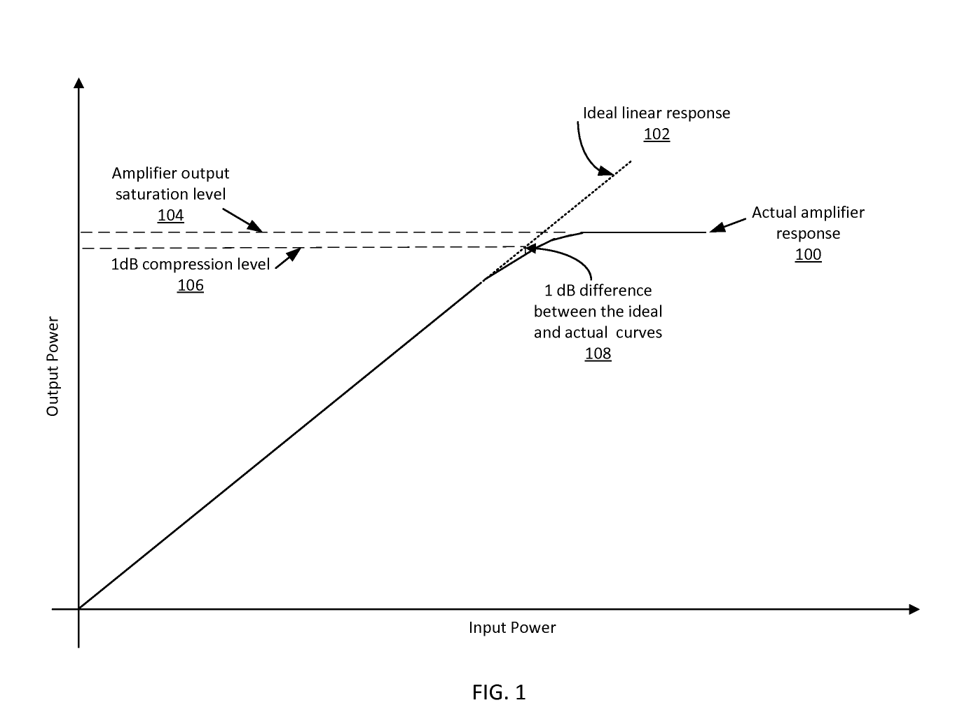

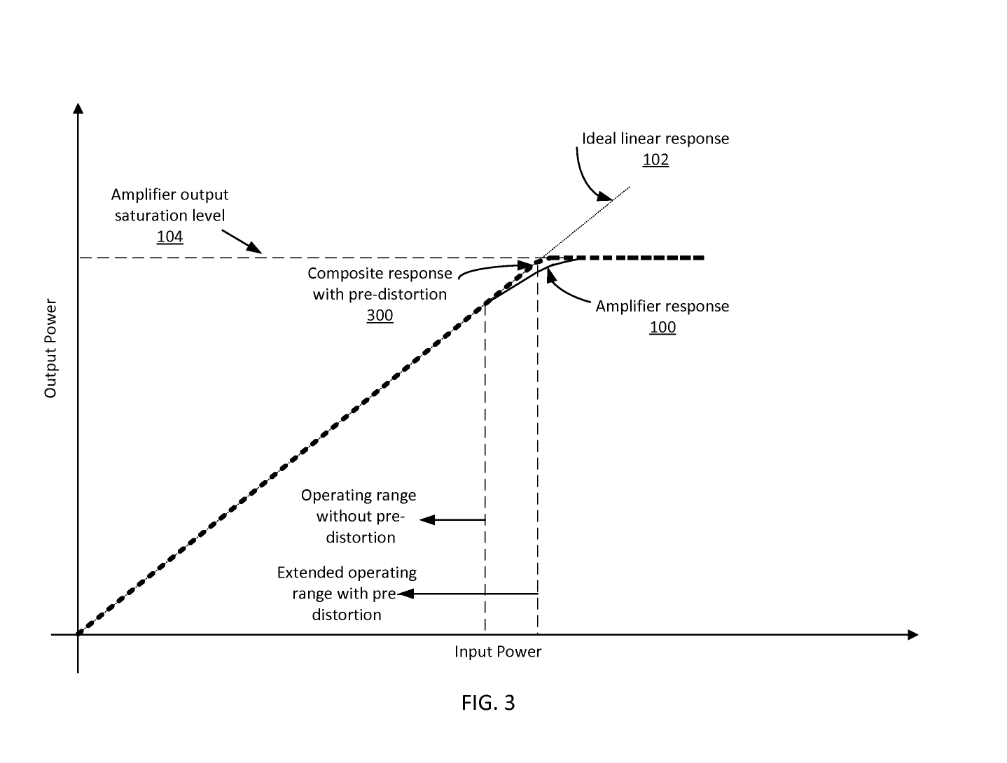

Solid line 100 of FIGS. 1 and 3 represents response of a typical power amplifier. This nonlinear response of most power amplifiers results in in-band and out-of-band distortion of the amplified output signal. Typically, the gain of a power amplifier for an input signal with a small magnitude is virtually constant. Thus, for small input power, the actual amplifier response 100 coincides with the ideal response 102 (represented as thin dotted line 102 in FIGS. 1 and 3).

The nonlinear portion (e.g., using the 1 dB compression point as a reference, the portion to the right of the 1 dB compression point) of the amplifier output versus input power curve is normally located at relatively high output power levels, as the amplifier response approaches the saturation level 104. The nonlinear distortion introduces out-of-band signal components that corrupt services operating over adjacent channels. Generally, in order to minimize the distortion introduced by the nonlinear region, the input power is backed-off, so that the operating region falls predominantly within the linear portion of the amplifier gain curve. However, this back-off negatively impacts the efficiency (average output power to power consumption ratio) of the amplifier. Thus, methods that enhance the efficiency of the power amplifiers and allow operation closer to its saturation level are desired.

One conventional method is to use predistortion which comprises intentionally introducing distortion to a signal prior to the signal being amplified by the nonlinear power amplifier such that the composite response is more linear than the response of the power amplifier alone. This is illustrated in FIG. 3 where the composite response with predistortion 300 deviates less from the ideal response 102 than does the response of the amplifier 100. The linearization composite response through digital predistortion enables the average output power of the power amplifier to be increased above the average output power of the power amplifier that could be tolerated without digital predistortion. Raising the average output power level enables the power amplifier to be operated more efficiently. Thus, conventional predistortion does have some benefits. In practice, however, the effectiveness of conventional predistortion in achieving higher performance is limited. Higher performance is achievable through the methods and system taught in this disclosure.

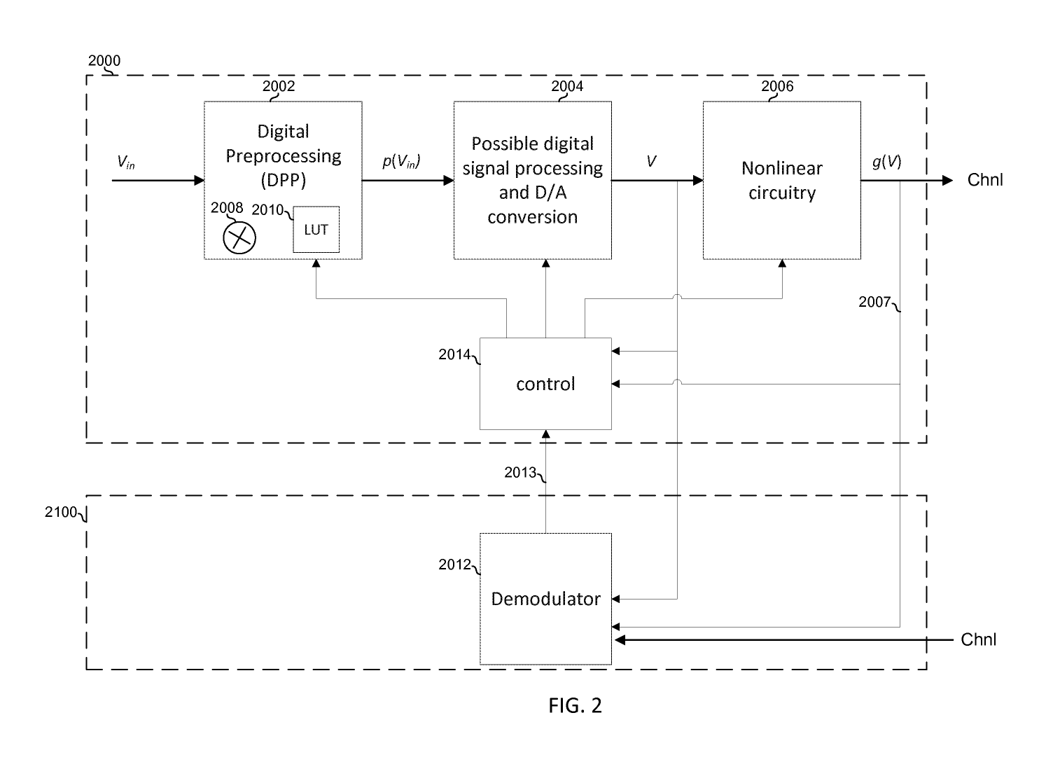

FIG. 2 depicts an example portion of a transmitter comprising digital preprocessing (DPP) circuit 2002, digital signal processing and digital-to-analog conversion circuitry 2004, and nonlinear circuitry 2006. The nonlinear circuitry 2006 may comprise, for example, an upconversion mixer and a power amplifier. Let us denote this voltage gain of the nonlinear circuitry 2006 by g. For such signals, the output signal Vₒᵤₜ is given by Vₒᵤₜ=g·Vᵢₙ, where Vᵢₙ is the input (voltage) signal. Its linear power gain is denoted by G=|g|². Above a certain signal level the amplifier no longer exhibits this linear behavior. For example, 1 dB of compression (illustrated by line 108) occurs at the level indicated by dashed line 106 in FIG. 1. For simplicity of notation, we can absorb the digital-to-analog conversion into the response of the power amplifier (or analog circuitry). In general, the amplifier gain, G, is modeled as an expression G(X) of the magnitude of an input sample, X. The gain G may have memory (in which case the amplifier output depends on some past input samples in addition to the present sample) or be memoryless. Typically, the amplifier gain decreases around its saturation or compression signal level. Above a certain signal level, represented as dashed line 104 in FIGS. 1 and 3, the output signal level saturates and no longer increases with the magnitude of the input signal. Likewise, the use of a memoryless model in which the amplifier output depends upon the input signal magnitude only is a simplification of the actual response of typical power amplifiers.

In an example implementation, digital processing is applied digitally to the baseband signal prior to up-conversion and amplification by the nonlinear circuitry 2006. In this regard, the DPP circuitry 2002 may implement some predefined expression X=p(Xᵢₙ), and produce an output sample, X, that depends on its input sample, Xᵢₙ, and optionally some past input samples. According to notation used in this disclosure, the output sample X feeds the nonlinear gain circuitry 2006 after being processed by circuitry 2004 (in some implementations, circuitry 2004 may be absent).

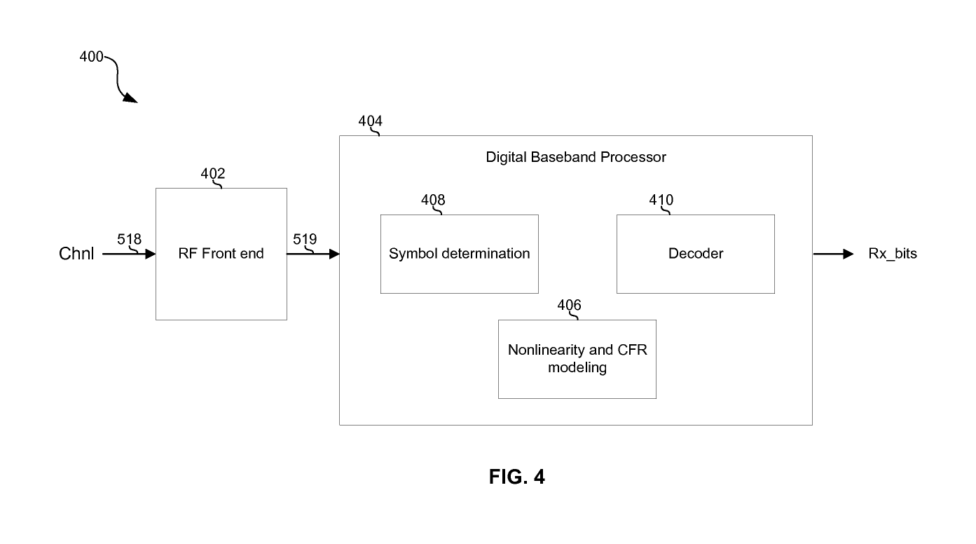

In an example implementation, digital preprocessing in the DPP circuitry 2002 comprises applying predistortion that is determined based on the response of the nonlinear circuitry 2006 and that results in the composite response of the transmitter 2000 that is not necessarily more linear than the response of the nonlinear circuitry 2006 (in fact, assuming for illustration that nonlinear circuitry 2006 consists of a power amplifier having the response 100 of FIG. 1, the composite response of the transmitter 2000 may have more and/or larger deviations from the ideal response 102 than does the actual amplifier response 100), but that results in nonlinear distortion that can be accurately reproduced in a receiver such as the receiver 400 of FIG. 4. The predistorting expression, p, is naturally a function of the magnitude of the input signal. In an example implementation, p may be implemented using a complex multiplier 2008 and a look-up table 2010 that accommodates the complex coefficients for the magnitude range of the input signal. In an example implementation, the parameters of p (e.g., complex coefficients) are acquired by an adaptive algorithm applied to a training signal. The adaptation algorithm depends on the type of nonlinearity model used to characterize the nonlinear behavior of the amplifier.

The nonlinear characteristic of the nonlinear gain circuitry 2006 involves high-order powers of the input signal (with or without memory). These nonlinear terms manifest themselves as both in-band and out-of-band distortion. Algorithms implemented by the DPP circuitry 2002 for adaptation/tuning of the DPP circuit 2002 may use a total characteristic curve as a target or cost function. Spectral constraints may be imposed on the DPP circuit 2002 so that it meets a determined nonlinear distortion profile in conjunction with applicable spectral mask limitations (e.g., set forth by a regulatory body such as the FCC in the United States, by ETSI in Europe, by 3GPP, IEEE). In an example implementation, the predistortion optimization problem may be transformed from the time domain to the frequency domain, and may use a weighed cost function that accounts for both the (in-band) distortion level (or equivalently, the EVM (Error Vector Magnitude)) and compliance to a spectral mask. These constraints may be used by the adaptation algorithm implemented in the transmitter 2000 to configure the power backoff of the nonlinear circuitry 2006 and/or predistortion parameters of the DPP circuitry 2002 (e.g., complex coefficients of expression p, parameters indicating one or more figures of merit to be achieved, and/or the like). The two constraints may be weighted according to the desired objectives. In an example implementation, EVM may be given little or no weight such that the power backoff of nonlinear circuitry 2006 and/or predistortion parameters of the DPP circuitry 2002 may adapt without regard to degradation in EVM, as long as compliance with the applicable spectral mask is maintained.

In an example implementation, digital preprocessing in the DPP circuitry 2002 comprises implementation of one or more crest factor reduction (CFR) or PAPR reduction algorithms such that p(Vᵢₙ) has lower PAPR than Vᵢₙ. Such methods may improve EVM and spectral mask compliance. As opposed to the aforementioned predistortion, the CFR methods operate on the transmitted signal to improve the envelope power statistics to tolerate the nonlinearities of the analog circuitry (e.g., power amplifier, mixer, DAC). Consequently, the transmitted power and the transmitted chain efficiency may improve. Such methods may be combined with predistortion techniques to further improve efficiency and increase the transmitted power.

Pre-compensation methods implemented by the DPP circuitry 2002 may operate in an open loop where the CFR and/or predistortion are configured according to given distortion models. The open loop schemes may use environmental indications such as temperature of the nonlinear circuitry 2006 and employ temperature dependent nonlinear models to adapt the predistortion parameters of the DPP circuitry 2002. The nonlinear model(s) may be measured/characterized during the production process. Pre-compensation methods implemented by the DPP circuitry 2002 may additionally, or alternatively, operate in an closed loop and may use a feedback of the transmitted signal g(V) with and without the DPP circuitry 2002 enabled to adapt the expression p implemented by DPP circuitry 2002. The feedback may be based on demodulation of the transmitted signal via, for example, demodulator 2012 of a local receiver 2100 residing in the same communication device (e.g., integrated on a single silicon die with the transmitter 2000) and/or in a remote receiver (e.g., if transmitter 2000 is in user equipment then the remote receiver may be in a basestation). The receiver may sense the distortion characteristic and distortion level and it may send an indication to the transmitter for dynamic adaptation.

Adaptation of predistortion parameters of the DPP circuitry 2002 and configuration of parameters of the CFR algorithm(s) implemented in the DPP circuitry 2002 may aim to increase the sustainable data rate (or equivalently, and/or reduce the power back-off and hence improve the power budget efficiency. This may be done with or without imposing some further spectral constraints that are typically targeted to comply with some in-band spectral mask and out-of-band mask decay specifications (where the specifications presume a conventional receiver that is unable to cope with nonlinear distortion and therefore expects substantially linear, distortion-free transmission).

In an example embodiment of this disclosure, the crest factor reduction algorithm used by the DPP circuitry 2002 and/or the distortion introduced by the DPP circuitry 2002 may be configured based on (e.g., to maximize, or to achieve at least a threshold amount of) transmitted power, system gain, and/or distance between possible transmitted symbols or symbol sequences, while complying with an determined spectral mask.

In an example embodiment of this disclosure, the crest factor reduction algorithm used by the DPP circuitry 2002 and/or the distortion introduced by the DPP circuitry 2002 may be configured based on (e.g., to minimize, or to achieve no more than a threshold amount of) mean-squared-error of a reconstructed signal (e.g., 603 and/or 607), symbol-error-rate in a receiver (e.g., a local receiver 2100 or learned through feedback from a remote receiver 400), and/or bit-error-rate while complying with a spectral mask in a receiver (e.g., a local receiver 2100 or learned through feedback from a remote receiver 400).

In an example embodiment of this disclosure, a receiver (e.g., 400 of FIG. 4) uses a CFR algorithm and composite nonlinearity model [symbol] (where the notation is such that, f_{NL} represents the actual nonlinear distortion introduced to the signal, and [symbol] is the receiver's model/approximation of the nonlinear distortion) the nonlinear distortion experienced by a received signal in order to reconstruct the transmitted information. In such an embodiment, the motivation of reducing the nonlinear distortion becomes less prominent, as the receiver plays a major role in eliminating the effects of nonlinear distortion. In this case, parameters of CFR and predistortion performed by the DPP circuitry 2002 may be adjusted according to requirements for [symbol] that are determined by the receiver's ability to tolerate the composite nonlinear distortion (some nonlinearity profiles may be simpler or harder to cope with at the receiver end than others) in addition to any specified spectral constraints. Therefore communication systems using the receiver-aided approach for mitigation of nonlinear effects disclosed herein achieve better performance (e.g., measured by SNR, power-efficiency, throughput, and/or other metrics) than conventional systems. The transmitter 2000 may be operated in its nonlinear range and introduce nonlinear distortion that reduces the signal-to-noise ratio (or EVM) of the transmitted signal as long as the signal meets the in-band and out-of-band spectral constraints. In an example implementation, the receiver may use demodulation techniques (in both cases of memory and memory-less nonlinear channel) that employ the known CFR algorithm and [symbol] in order to reconstruct the signal that best matches the received signal. In an example implementation, the nonlinear distortion introduced by the transmitter (in nonlinear element 2006 and DPP circuitry 2002) may dominate and, accordingly, [symbol] may account for distortion in the transmitter while ignoring distortion introduced in the receiver. In another implementation, [symbol] may also account for nonlinear distortion introduced in the receiver. The receiver 400 may sense the level and/or other characteristics of the nonlinear distortion and indicate it back to the transmitter (via an in-band or out-of-band control channel) such that the transmitter may use if for configuring the DPP circuitry 2002 and nonlinear circuitry 2006.

Nonlinear model f_{NL} can be expressed as a plurality of terms (e.g., through series expansion). Each term may differ, for example, by polynomial order and/or time domain dependence (e.g., some terms may be causal and others may be non-causal). In an example implementation, a first subset of the plurality of terms may be accounted for in the DPP circuitry 2002 of the transmitter and a second subset of the plurality of terms may be accounted for in the digital baseband processor of the receiver. For example, due to implementation limitations of the nonlinear model [symbol] in the receiver (e.g., causality and complexity limitations that may be associated with the high-order terms of the expression of nonlinearity), it may be more cost effective to compensate for the high-order terms of f_{NL} in the DPP circuitry 2002 and have [symbol] be an estimate of only the low-order terms of f_{NL}. Separation of the nonlinear handling between transmitter and receiver may provide optimal system gain performance (i.e., power backoff and sensitivity) by effective load balance between transmitter and receiver. For example, attempting to compensate for too many nonlinear terms at the transmitter by DPP 2002 and/or circuit 2004 may increase the dynamic range of the input (V) to the nonlinear circuitry 2006 which may result with an excitation of new nonlinear terms that may degrade system performance.

The control circuitry 2014 may be operable to sense characteristics of the output of DPP circuitry 2002, the output of circuitry 2004, the output of the nonlinear circuitry 2006, a demodulated version of V output on bus 2013 by demodulator 2012, and/or a demodulated version of g(V) output on bus 2013 by the demodulator 2012. The control circuitry 2014 may be operable to dynamically adapt the DPP circuitry 2002 (e.g., adapt predistortion and/or CFR parameters), the circuitry 2004, and/or the nonlinear circuitry 2006 (e.g., power backoff) based on the sensed characteristics. The characteristics may include, for example, the spectral content of the sensed signal(s) (e.g., measured as power spectral density) and/or the magnitude of the sensed signal(s), the error vector magnitude of the sensed signal(s), and/or the like. The adaptation of the DPP circuitry 2002 (CFR and/or predistortion), the circuitry 2004, and/or the nonlinear circuitry 2006 may be indicated to the receiver side to maintain detection performance. The control circuitry 2014 may, for example, be operable to inject parameters into a signal transmitted during connection setup with a partner receiver. The parameters may, for example, be injected into a preamble of a signal sent to be sent to a partner receiver, and/or into headers of messages to be sent to a partner receiver.

In an example embodiment of the disclosure, partial response pulse shaping may be used in order to improve tolerance to nonlinearity. The transmit signal in such a system intentionally has a substantial amount of inter-symbol interference (ISI). In this regard, the ISI is therefore a controlled ISI. It should be noted that a partial response signal (or signals in the “partial response domain”) is just one example of a type of signal for which there is correlation among symbols of the signal (referred to herein as “inter-symbol-correlated (ISC) signals”). Such ISC signals are in contrast to zero (or near-zero) ISI signals generated by, for example, a raised-cosine (RC) shaping filter. For simplicity of illustration, this disclosure focuses on partial response signals generated via partial response filtering. Nevertheless, aspects of this disclosure are applicable to other ISC signals such as, for example, signals generated via matrix multiplication (e.g., lattice coding), and signals generated via decimation below the Nyquist frequency such that aliasing creates correlation between symbols.

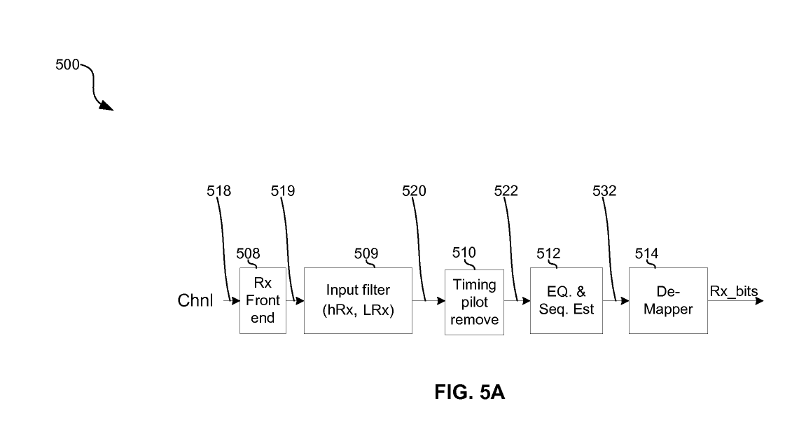

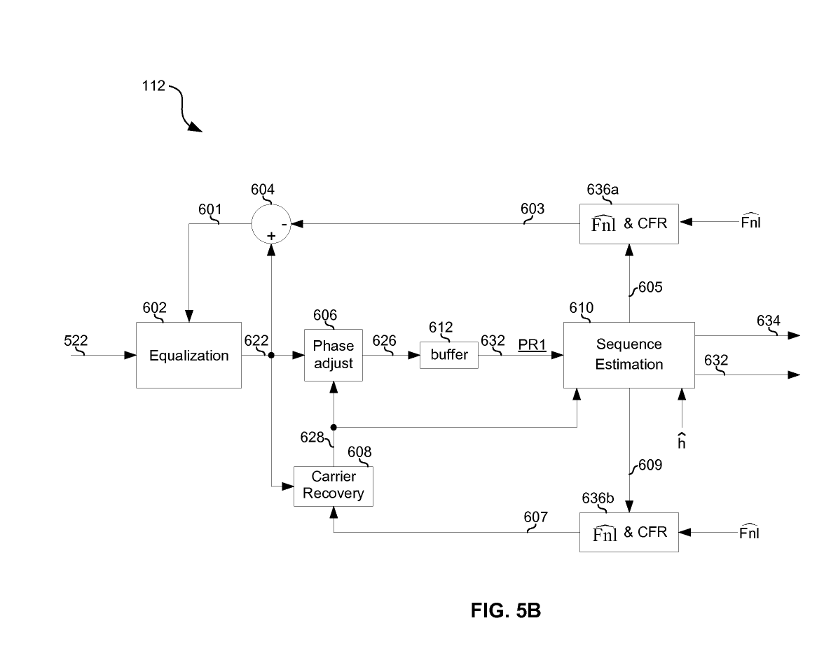

In an example embodiment of the disclosure, the configuration/optimization of the CFR and predistortion may be carried out in a wider scope of the whole system rather than that of the transmission only. The predistortion and/or CFR parameters may be derived from an optimization problem using a performance figure of merit of the whole system that consists of the nonlinear transmitter and the receiver that uses this model. This figure of merit may be the system gain (the ratio between transmitted power and receiver sensitivity), mean-squared-error of the reconstructed signal at the demodulator output, bit error rate (BER), some measure of (minimum) distance between transmitted sequences, or the like. In an example implementation using sequence estimation (such as the example implementation described below with reference to FIGS. 4 and 5), this figure of merit may also combine some complexity constraints derived from the implications of the composite transmitter-receiver response on the sequence-estimation-based demodulator. These constraints may be combined with some other spectral and/or EVM constraints by weighting the different constraints according to the design goals.

FIG. 4 is a block diagram of a receiver configured for receiver-aided mitigation of nonlinear effects. The receiver comprises RF front-end circuitry 402 and digital baseband processing circuitry 404. The RF front-end 402 may comprise, for example, a low noise amplifier, downconverter, one or more filters, and an analog-to-digital converter. The RF front end is operable to receive signal 518 over the channel and process the signal to output corresponding digital baseband signal 519. The signal 519 may be a single-carrier signal or a multi-carrier signal (e.g., an orthogonal frequency division multiplexed (OFDM) signal).

The digital baseband processing circuitry 404 is operable to process the digital baseband signal 519 to recover information carried in the signal. The digital baseband processing circuitry 404 comprises symbol determination circuitry 408, nonlinearity and CFR modeling circuitry 406, and decoder 410.

In operation, the digital baseband processor 408 may take a maximum likelihood based approach to determining the transmitted symbols that resulted in the signal 519. To this end, the modeling circuitry 406 may generate the model, [symbol] , of the nonlinearity experienced by the signal 519 (e.g., including the nonlinearity of the DPP circuitry 2002 and the nonlinear circuitry 2006) and may be operable to perform a CFR algorithm that is the same as, or complimentary to, a CFR algorithm performed in a transmitter from which the signal 518 was received.

In an example implementation, the signal 519 may be processed to cancel/compensate for CFR and/or distortion introduced by the transmitter from which the signal 519 originated. In this regard, an inverse of [symbol] (provided by modeling circuitry 406) may be applied to the signal 519 by the symbol determination circuitry 408 to cancel/compensate for the nonlinear distortion introduced by the transmitter and a CFR algorithm (e.g., provided by modeling circuitry 406) that is complimentary to (e.g., that reverses to the extent possible) the CFR algorithm implemented in the transmitter from which signal 519 originated may be applied, by symbol determination circuitry 408, to the signal 519 to cancel/compensate for the CFR. After cancelling/compensating for the nonlinear distortion and the CFR, the symbol determination module 408 may slice the resulting symbol according to the symbol constellation in use (e.g., N-QAM) and output the resulting hard and/or soft decisions to the decoder 410, which may implement an FEC decoding algorithm to determine the transmitted bits corresponding to the decisions from the symbol determination module 408.

In an example implementation, [symbol] and the CFR algorithm implemented in the transmitter from which the signal 519 originated may be provided from the modeling circuitry 406 to the symbol determination circuitry 408 and the symbol determination circuitry 408 may apply the model and the CFR algorithm to one or more hypotheses of the transmitted symbols corresponding to the received signal 519. The result is one or more distorted and crest-factor-reduced hypotheses. The symbol determination circuitry 408 may then calculate an error between the received signal 519 and the one or more distorted and crest-factor-reduced hypotheses to determine whether the hypothesis was good or which of the hypotheses was best. The symbol determination circuitry 408 then outputs a good (or best) hypothesis in the form of soft and/or hard symbol decisions, and the decoder 410 decodes the symbols to recover the transmitted bitstream.

The receiver 400 may generate the nonlinearity model and/or determine the CFR algorithm based on parameters characterizing nonlinearity and/or crest factor reduction algorithm of the transmitter from which the signal 518 originated. Such characteristics may include, for example, parameters (e.g., gain, 1 dB compression point, power backoff, etc.) characterizing a power amplifier of the nonlinear gain circuitry 2006 and/or parameters (e.g., complex coefficients of the expression p, input power at which signal is clipped, output power level to which the signal is clipped, etc.) characterizing the DPP circuit 2002. Such characteristics may, for example, be transmitted to the receiver 400 during connection setup (e.g., in preambles or headers, via a low-bandwidth out-of-band control channel, and/or the like).

FIGS. 5A and 5B depict an example sequence-estimation-based implementation of the receiver of receiver FIG. 4. Referring to FIG. 5A, the system 500 comprises a receiver front-end 508, a filter circuit 509, a timing pilot removal circuit 510, an equalization and sequence estimation circuit 512, and a de-mapping circuit 514. The receiver may receive signals from a transmitter, such as the transmitter 2000 of FIG. 2) via the channel. The sequence estimation circuit 112 may be an implementation of the symbol determination circuitry 408.

The channel may comprise a wired, wireless, and/or optical communication medium. The signal output by the nonlinear element 2006 may propagate through the channel and arrive at the RF front-end 402 as signal 518. Signal 518 may be noisier than signal output by the nonlinear element 2006 (e.g., as a result of thermal noise in the channel) and may have higher or different ISI than signal output by the nonlinear element 2006 (e.g., as a result of multi-path).

The receiver front-end 508 is operable to amplify, downconvert, and digitize the signal 518 to generate the signal 519. Thus, the receiver front-end may comprise, for example, a low-noise amplifier and/or a mixer. The receiver front-end may introduce nonlinear distortion and/or phase noise to the signal 519.

The timing pilot recovery and removal circuit 510 is operable to lock to a timing pilot signal inserted by transmitter in order to recover the symbol timing of the received signal. The output signal 522 may thus comprise the signal 520 minus (i.e., without) the timing pilot signal.

The input filter 509 is operable to adjust the waveform of the signal 519 to generate the signal 520. The input filter 509 may comprise, for example, an infinite impulse response (IIR) and/or a finite impulse response (FIR) filter. The number of taps, or “length,” of the input filter 509 is denoted herein as LRx, an integer. The impulse response of the input filter 509 is denoted herein as hRx. The number of taps, and/or tap coefficients of the input filter 509 may be configured based on: the nonlinearity model, [symbol] , signal-to-noise ratio (SNR) of signal 520, the number of taps and/or tap coefficients of a pulse-shaping filter of the transmitter 2000, and/or other parameters. The number of taps and/or the values of the tap coefficients of the input filter 509 may be configured such that noise rejection is intentionally compromised (relative to a perfect match filter) in order to improve performance in the presence of nonlinearity. As a result, the input filter 509 may offer superior performance in the presence of nonlinearity as compared to, for example, a conventional near zero positive ISI matching filter (e.g., root raised cosine (RRC) matched filter).

The equalizer and sequence estimation circuit 512 may be operable to perform an equalization process and a sequence estimation process. Details of an example implementation of the equalizer and sequence estimation circuit 512 are described below with respect to FIG. 5B. The output signal 532 of the equalizer and estimation circuit 512 may be in the symbol domain and may carry estimated values of the transmitted symbols (and/or estimated values of transmitted information bits) that resulted in the received signal. Although not depicted, the signal 532 may pass through an interleaver en route to the de-mapper 514. The estimated values may comprise soft-decision estimates, hard-decision estimates, or both.

The de-mapper 514 may be operable to map symbols to bit sequences according to a selected modulation scheme. For example, for an N-QAM modulation scheme, the mapper may map each symbol to Log₂(N) bits of the Rx_bitstream. The Rx_bitstream may, for example, be output to a de-interleaver and/or an FEC decoder. Alternatively, or additionally, the de-mapper 514 may generate a soft output for each bit, referred as LLR (Log-Likelihood Ratio). The soft output bits may be used by a soft-decoding forward error corrector (e.g. a low-density parity check (LDPC) decoder). The soft output bits may be generated using, for example, a Soft Output Viterbi Algorithm (SOVA) or similar. Such algorithms may use additional information of the sequence decoding process including metrics levels of dropped paths and/or estimated bit probabilities for generating the LLR, where

$$LLR ( b ) = log ( \frac{{P}_{b}}{1 - {P}_{b}} ) ,$$

where P_{b} is the probability that bit b=1.

Referring to FIG. 5B there is shown a block diagram depicting an example implementation of the equalization and sequence estimation circuit of FIG. 5A. Shown are an equalizer circuit 602, a signal combiner circuit 604, a phase adjust circuit 606, a sequence estimation circuit 610, a buffer 612, and nonlinearity and crest factor reduction modeling circuits 636a and 636b.

The equalizer 602 is operable to process the signal 522 to reduce ISI caused by the channel (e.g., due to multipath). The output 622 of the equalizer 602 is a partial response domain signal. The ISI of the signal 622 is primarily the result of ISI introduced in the transmitter 2000 (there may, however, be some residual ISI from multipath, for example, due to use of the least means square (LMS) approach in the equalizer 602). The error signal, 601, fed back to the equalizer 602 is also in the partial response domain. The signal 601 is the difference, calculated by combiner 604, between 622 and a partial response signal 603 that is output by nonlinearity and crest factor reduction modeling circuit 636a.

The carrier recovery circuit 608 is operable to generate a signal 628 based on a phase difference between the signal 622 and a partial response signal 607 output by the nonlinearity and crest factor reduction modeling circuit 636b.

The phase adjust circuit 606 is operable to adjust the phase of the signal 622 to generate the signal 626. The amount and direction of the phase adjustment may be determined by the signal 628 output by the carrier recovery circuit 608. The signal 626 is a partial response signal that approximates (up to an equalization error caused by finite length of the equalizer 602, a residual phase error not corrected by the phase adjust circuit 606, nonlinearities, and/or other non-idealities) the total partial response signal resulting from corresponding transmitted symbols passing through circuitry that introduces ISI.

The buffer 612 buffers samples of the signal 626 and outputs a plurality of samples of the signal 626 via signal 632. The signal 632 is denoted PR1, where the underlining indicates that it is a vector (in this case each element of the vector corresponds to a sample of a partial response signal). In an example implementation, the length of the vector PR1 may be Q samples.

Input to the sequence estimation circuit 610 are the signal 632, the signal 628, and a response ĥ. Response ĥ is an estimate of the channel response, which may account for multipath and/or other non-idealities in the channel, the effects of pulse shaping and/or other operations that were performed in the transmitter, and/or effects of the RX filter 508. The response ĥ may be conveyed and/or stored in the form of one or more tap coefficients. The sequence estimation circuit 610 may output feedback signals 605 and 609, a signal 634 that corresponds to the finely determined phase error of the signal 520, and signal 632 (which carries hard and/or soft estimates of transmitted symbols and/or transmitted bits).

The nonlinearity and crest factor reduction modeling circuit 636a may apply the nonlinearity model [symbol] and/or a crest factor reduction algorithm (the crest factor reduction algorithm applied in the transmitter from which the signal 522 is received) to the signal 605 resulting in the signal 603. Similarly, the modeling circuit 636b may apply the nonlinearity model [symbol] and/or a crest factor reduction algorithm (the crest factor reduction algorithm applied in the transmitter from which the signal 518 is received) to the signal 609 resulting in the signal 607. [symbol] may be, for example, a third-order or fifth-order polynomial. Increased accuracy resulting from the use of a higher-order polynomial for [symbol] may tradeoff with increased complexity of implementing a higher-order polynomial. Accordingly, as discussed above, [symbol] may approximate only the lower-order terms while the higher-order terms are compensated for by predistortion in the transmitter. In the example implementation of FIG. 5B, the signal 603 is used for adapting the equalizer and the signal 607 is used for adapting the carrier recovery circuitry 606.

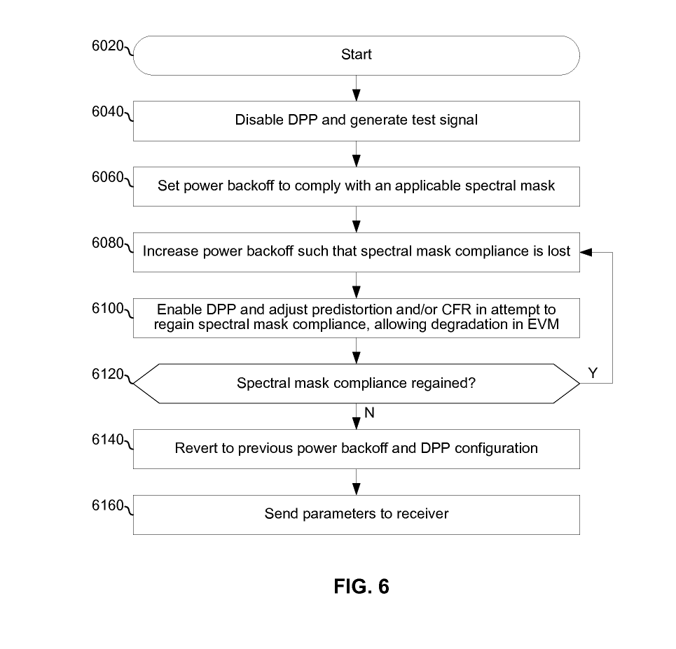

FIG. 6 is a flowchart illustrating an example process for configuration of a transmitter. In block 6040, after start block 6020, the DPP circuitry 2002 is disabled and a test signal of determined characteristics (e.g., symbol rate, modulation order, etc.) is input to nonlinear circuitry 2006. In block 6060, the power backoff of the nonlinear circuitry 2006 is set such that the output of the nonlinear circuitry 2006 complies with an applicable spectral mask. In block 6080, the power backoff of nonlinear circuitry 2006 is decreased such that nonlinear distortion introduced by the nonlinear circuitry 2006 causes increased out-of-band distortion such that the output of the nonlinear circuitry 2006 no longer complies with the applicable spectral mask. In block 6100, the DPP circuitry 2002 is enabled and adaptively configured in an attempt to regain compliance with the applicable spectral mask. The adaptive configuration may alter the predistortion and/or crest factor reduction applied by the DPP circuitry 2002. The adaptive configuration may be performed without regard to the EVM of the transmitter 2000 (in fact, the EVM may even degrade). In block 6120, if spectral mask compliance is regained through the adaptive configuration of the DPP circuitry 2002, then the process returns to block 608. Still in block 6120, if spectral mask compliance cannot be regained through the adaptive configuration of the DPP circuitry 2002, then the process advances to block 614. In block 6140, the DPP circuitry 2002 reverts back to the last configuration in which spectral mask compliance was achieved. In block 6160, parameters corresponding to the configuration of the DPP circuitry 2002 at the completion of block 6140 are transmitted for use by receivers which may desire to receive transmissions from the transmitter 2000.

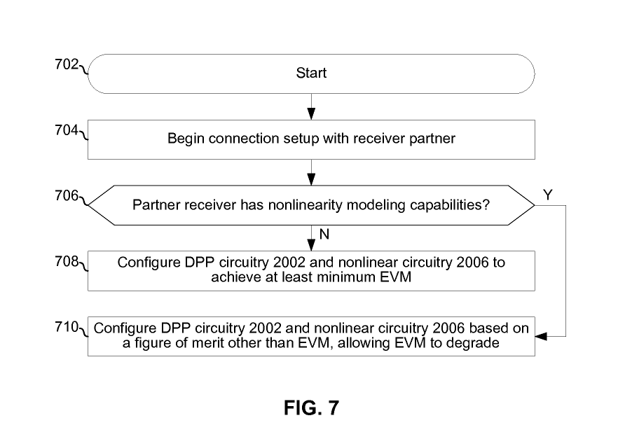

FIG. 7 is a flowchart illustrating an example process for configuration of a transmitter. In block 714, after start block 702, the transmitter 2000 begins connection setup with a receiver partner such as 400 of FIG. 4. In block 706, the transmitter 2000 determines whether the receiver partner has nonlinearity modeling capabilities such as are present in digital baseband processor 404. If not, then the process advances to block 708 and the DPP circuitry 2002 and nonlinear circuitry 2006 are configured to achieve at least some minimum EVM while complying with an applicable spectral mask. Returning to block 706, if the partner receiver does have nonlinearity modeling capabilities such as are present in digital baseband processor 404, then the process advances to block 710. In block 710, the DPP circuitry 2002 and nonlinear circuitry 2006 are configured based on a figure of merit other than EVM (e.g., power efficiency; transmitted power; BER, PER, SNR and/or some other figure of merit reported by a receiver partner; and/or the like). During the configuration in block 710, the EVM may actually degrade yet overall system performance may increase because of the capabilities of a receiver partner such as receiver 400 to handle the nonlinearity. In this manner, the transmitter and receiver may participate in a negotiation/connection setup that enables the transmitter to be backwards compatible with receivers that do not have the nonlinearity modeling capabilities. In an example implementation, the DPP 2002 may support three modes: a mode in which the DPP 2002 is disabled or bypassed, resulting in a first EVM, a second (legacy) mode in which the DPP 2002 is configured based on spectral mask compliance and EVM (e.g., to optimize EVM or at least keep it below some threshold), and a third mode in which the DPP 2002 is configured based spectral mask compliance on some figure of merit other than EVM (e.g., to maximize power amplifier efficiency, even if maximum power efficiency corresponds to a less than optimum EVM).

In accordance with an example implementation of this disclosure, circuitry of a transmitter may comprise a predistortion circuit (e.g., 2002) cascaded with a nonlinear circuit (e.g., 2006). The nonlinear circuit is characterized by a first response corresponding to a first error vector magnitude. A response of the predistortion circuit may be configured based on the first response of the nonlinear circuit such that a composite response of the predistortion circuit cascaded with the nonlinear circuit differs from the first response and is characterized by a second error vector magnitude that is greater or equal than the first error vector magnitude. The response of the predistortion circuit may be configured based on feedback of an output of the nonlinear circuit (e.g., signal 2007). The response of the predistortion circuit may be configured based on parameters received from a receiver partner (e.g., 400) of the transmitter during connection setup, in preambles, in message headers, and/or in dedicated messages. The parameters may indicate a figure of merit such as bit error rate, packet error rate, signal-to-noise ratio, and/or the like. The nonlinear circuit may comprise a power amplifier and the response of the predistortion circuit may be configured based on a power backoff setting of the power amplifier. The response of the predistortion circuit may be characterized by one or more predistortion parameters, which the circuitry of the transmitter may be operable to transmit the one or more predistortion parameters during connection setup, in preambles, in message headers, and/or in dedicated messages. The response of the predistortion circuit may be configured to compensate for a first portion of a nonlinearity of the response of the nonlinear circuit but not compensate for a second portion of the nonlinearity of the response of the nonlinear circuit. The nonlinearity of the nonlinear circuit may be expressed as a sum of a plurality of terms. The first portion of the nonlinearity of the response of nonlinear circuit may correspond to a subset of higher-order terms of the plurality of terms and/or corresponds to a subset of the plurality of terms consisting of non-causal terms of the plurality of terms.

In accordance with an example implementation of this disclosure, circuitry of a transmitter may comprise a predistortion circuit cascaded with a nonlinear circuit. A composite response of the predistortion circuit cascaded with the nonlinear circuit may be characterized by a first error vector magnitude when the predistortion circuit is enabled and may be characterized by a second error vector magnitude when the predistortion circuit is disabled, where the first error vector magnitude is greater than the second error vector magnitude.

In accordance with an example implementation of this disclosure, a receiver (e.g., 400) may comprise a modeling circuit (e.g., 406) and a symbol determination circuit (e.g., 408), wherein the modeling circuit is operable to generate a model of a portion of a nonlinear distortion experienced by a received signal (e.g., 519) en route to the modeling circuit. The symbol determination circuitry may be operable to process a received signal using the model of the portion of the nonlinear distortion to decide one or more transmitted symbols (e.g., QAM symbols) corresponding to the received signal. When the nonlinear distortion is expressed as a sum of a plurality of terms, the portion of the nonlinear distortion may correspond to causal terms of the plurality of terms and not non-causal terms of the plurality of terms, and/or may correspond to higher-order terms of the plurality of terms and not lower-order terms of the plurality of terms. The modeling circuit may be operable to generate the model of the nonlinear distortion based on parameters characterizing nonlinearity of a transmitter from which the received signal originated. The receiver may be operable to receive the parameters characterizing the nonlinearity of the transmitter from the transmitter during connection setup, in preambles, in message headers, and/or in dedicated messages. The parameters may characterize a response of a power amplifier (e.g., the nonlinear circuit 2006) of the transmitter. The parameters may characterize digital predistortion implemented in the transmitter. The modeling circuitry may be operable to perform a crest factor reduction algorithm that is the same as, or complimentary to, a crest factor reduction algorithm implemented in a transmitter from which the receive signal originated. The symbol determination circuit may comprise an equalizer (e.g., 602) that is adapted based on a feedback signal (e.g., 603 or 607). The symbol determination circuitry may be operable to apply the model of the nonlinear distortion to symbol decisions (e.g., signals 605 and 609) to generate the feedback signal. The symbol determination circuitry may be operable to apply a crest factor reduction algorithm to the symbol decisions to generate the feedback signal.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip. Some implementations may comprise a non-transitory machine-readable (e.g., computer readable) medium (e.g., FLASH drive, optical disk, magnetic storage disk, or the like) having stored thereon one or more lines of code executable by a machine, thereby causing the machine to perform processes as described herein.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system comprising:
circuitry of a transmitter comprising a predistortion circuit cascaded with a nonlinear circuit, wherein:
said nonlinear circuit is characterized by a first response corresponding to a first error vector magnitude; and
a response of said predistortion circuit is configured based on said first response of said nonlinear circuit such that a composite response of said predistortion circuit cascaded with said nonlinear circuit differs from said first response and is characterized by a second error vector magnitude that is greater or equal than said first error vector magnitude.

2. The system of claim 1, wherein said response of said predistortion circuit is configured based on feedback of an output of said nonlinear circuit.

3. The system of claim 1, wherein said response of said predistortion circuit is configured based on parameters received from a receiver partner of said transmitter during connection setup, in preambles, in message headers, and/or in dedicated messages.

4. The system of claim 3, wherein said parameters indicate a figure of merit.

5. The system of claim 1, wherein said nonlinear circuit comprises a power amplifier.

6. The system of claim 5, wherein said response of said predistortion circuit is configured based on a power backoff setting of said power amplifier.

7. The system of claim 1, wherein:
said response of said predistortion circuit is characterized by one or more predistortion parameters; and
said circuitry of said transmitter is operable to transmit said one or more predistortion parameters during connection setup, in preambles, in message headers, and/or in dedicated messages.

8. The system of claim 1, wherein said response of said predistortion circuit is configured to compensate for a first portion of a nonlinearity of said response of said nonlinear circuit but not compensate for a second portion of said nonlinearity of said response of said nonlinear circuit.

9. The system of claim 8, wherein:
said nonlinearity of said nonlinear circuit can be expressed as a sum of a plurality of terms; and
said first portion of said nonlinearity of said response of nonlinear circuit corresponds to a subset of higher-order terms of said plurality of terms.

10. The system of claim 8, wherein:
said nonlinearity of said nonlinear circuit can be expressed as a sum of a plurality of terms; and
said first portion of said nonlinearity of said response of nonlinear circuit corresponds to a subset of said plurality of terms consisting of non-causal terms of said plurality of terms.

11. A system comprising:
circuitry of a transmitter comprising a predistortion circuit cascaded with a nonlinear circuit, wherein:
a composite response of said predistortion circuit cascaded with said nonlinear circuit is characterized by a first error vector magnitude when said predistortion circuit is enabled;
said composite response of said predistortion circuit cascaded with said nonlinear circuit is characterized by a second error vector magnitude when said predistortion circuit is disabled; and
said first error vector magnitude is greater than said second error vector magnitude.

12. The system of claim 11, wherein said response of said predistortion circuit is configured based on feedback of an output of said nonlinear circuit.

13. The system of claim 11, wherein said response of said predistortion circuit is configured based on parameters received from a receiver partner of said transmitter during connection setup, in preambles, in message headers, and/or in dedicated messages.

14. The system of claim 13, wherein said parameters indicate a figure of merit.

15. The system of claim 13, wherein said nonlinear circuit comprises a power amplifier.

16. The system of claim 15, wherein said predistortion circuit is configured based on a power backoff setting of said power amplifier.

17. The system of claim 11, wherein:
said predistortion circuit is configured via one or more predistortion parameters; and
said circuitry of said transmitter is operable to transmit said one or more predistortion parameters during connection setup, in preambles, in message headers, and/or in dedicated messages.

18. The system of claim 11, wherein said predistortion circuit is configured to compensate for a first portion of a nonlinearity of a response of said nonlinear circuit but not compensate for a second portion of said nonlinearity of said response of said nonlinear circuit.

19. The system of claim 18, wherein:
said nonlinearity of said nonlinear circuit can be expressed as a sum of a plurality of terms; and
said first portion of said nonlinearity of said response of nonlinear circuit corresponds to a subset of higher-order terms of a said plurality of terms.

20. The system of claim 18, wherein:
said nonlinearity of said nonlinear circuit can be expressed as a sum of a plurality of terms; and
said first portion of said nonlinearity of said response of nonlinear circuit corresponds to a subset of said plurality of terms consisting of non-causal terms of said plurality of terms.
